(19) United States
(12) Patent Application Publication
(10) Pub. No.: US 2019/0019716 A1
(43) Pub. Date: Jan. 17, 2019

(54) HEAT TRANSFER SHEET AND SUBSTRATE PROCESSING APPARATUS

(71) Applicant: Tokyo Electron Limited, Tokyo (JP)

(72) Inventor: Ryo SASAKI, Miyagi (JP)

(21) Appl. No.: 16/029,749

(22) Filed: Jul. 9, 2018

(30) Foreign Application Priority Data
Jul. 13, 2017 (JP) 2017-137322

(51) Int. Cl. H01L 21/683; H01L 21/67; H01L 21/687

(52) U.S. Cl. CPC H01L 21/6835; H01L 21/6831; H01L 21/68735; H01L 21/67063

(57) ABSTRACT

A heat transfer sheet formed of a plurality of layers provided between a mounting stage and a focus ring on an outer side of a substrate to be mounted on the mounting stage inside a plasma treatment apparatus, wherein the plurality of layers includes a heat insulating layer having thermal conductivity lower than thermal conductivity of the focus ring, and an adhesive layer having adhesiveness higher than adhesiveness of the heat insulating layer.

### CROSS-REFERENCE TO RELATED APPLICATIONS

This patent application is based upon and claims the benefit of priority of Japanese Patent Application No. 2017-137322 filed on Jul. 13, 2017, the entire contents of which are incorporated herein by reference.

### BACKGROUND OF THE INVENTION

### 1. Field of the Invention

The present invention relates to a heat transfer sheet and a substrate processing apparatus.

### 2. Description of the Related Art

One example of a substrate processing apparatus including a heat transfer sheet between a mounting stage and a focus ring has a heat insulating layer having a thermal conductivity lower than that of the focus ring on a surface of the focus ring on a side of the heat transfer sheet (see Patent Document 1). According to Patent Document 1, by forming the heat insulating layer on the surface of the focus ring on the side of the heat transfer sheet, it is possible to increase a temperature change occurring inside the focus ring. As a result, even if the temperature of the upper surface of the focus ring becomes 200° C. or greater by heat affected by the plasma at a time of a high temperature process, the temperature of the lower surface (a lower surface of the heat insulating layer) of the focus ring can be maintained to be about 160° C. [Patent Document 1] Japanese Laid-open Patent Publication No. 2016-39344

### SUMMARY OF THE INVENTION

A heat transfer sheet formed of a plurality of layers provided between a mounting stage and a focus ring on an outer side of a substrate to be mounted on the mounting stage inside a plasma treatment apparatus, wherein the plurality of layers includes a heat insulating layer having thermal conductivity lower than thermal conductivity of the focus ring, and an adhesive layer having adhesiveness higher than adhesiveness of the heat insulating layer.

### BRIEF DESCRIPTION OF THE DRAWINGS

FIG. 1 illustrates an example of a heat transfer sheet of a mounting stage according to an embodiment.

FIG. 2 is a cross-sectional view of an example of a structure of a substrate processing apparatus of the embodiment.

FIGS. 3A-3C illustrate examples of structures of heat transfer sheets of the embodiment.

FIGS. 4A and 4B illustrate properties of heat transfer sheets of the embodiment and a comparative example for comparison.

FIG. 5 illustrates properties of the heat transfer sheets of the embodiment and the comparative example for comparison.

FIG. 6 illustrates a tension test of the embodiment.

FIGS. 7A-7C illustrate an example of a procedure of the tension test of the embodiment.

FIG. 8 illustrates a relation between a time after plasma firing and displacement of the embodiment.

FIG. 9 illustrates an example of a tension test result of the heat transfer sheet of the embodiment.

### DETAILED DESCRIPTION OF EMBODIMENTS

However, when this heat transfer sheet is used for a high temperature process of 250° C. or higher, oil bleeding occurs in this heat transfer sheet so as to cause the silicone oil to impregnate into the heat insulating layer of the focus ring. Therefore, after repeatedly using the heat transfer sheet, a thermal resistance value of the heat insulating layer changes. Therefore, it becomes difficult to maintain repeatability of etching property. Further, in a process of repeating the thermal cycle, the coefficient of thermal expansion of the heat transfer sheet may change depending on the temperature so as to cause the heat transfer sheet to peel off. Meanwhile, when the focus ring is processed to obtain a predetermined property every time the focus ring is replaced, the focus ring is required to, be repeatedly processed. The labor and cost for this repeated processing is not realistically compensated.

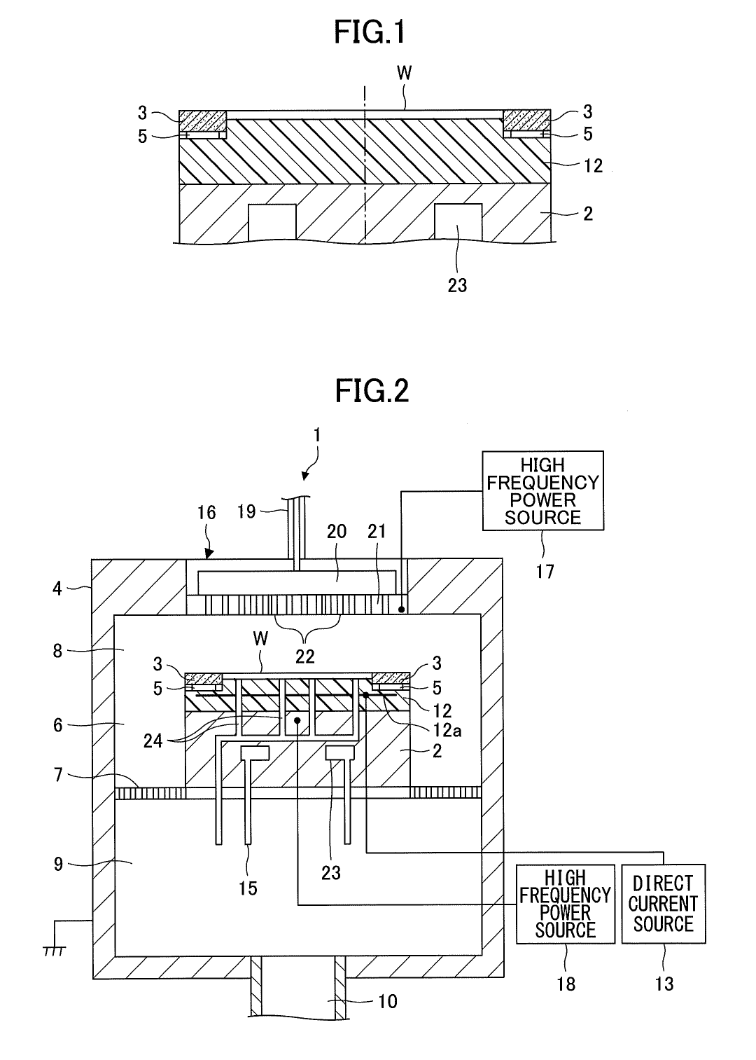

A description of embodiments of the present invention is given below, with reference to the FIG. 1 through FIG. 9.

The embodiments described below are only examples and the present invention is not limited to the embodiments.

Through all figures illustrating the embodiments, the same references symbols are used for portions having the same function, and repetitive explanations of these portions are omitted.

Reference symbols typically designate as follows:
1: substrate processing apparatus
2: mounting stage
3: focus ring
4: chamber
5: heat transfer sheet
5a: heat insulating layer
5b: follow layer
5c: adhesive layer
5d: thermal diffusion layer
7: exhaust plate
8: reaction chamber
9: exhaust chamber
12: electrostatic chuck
12a: adsorption electrode
13: direct current source
16: gas shower head
17: high frequency power source
18: high frequency power source
23: refrigerant flow passage

### Example of Structure of Mounting Stage

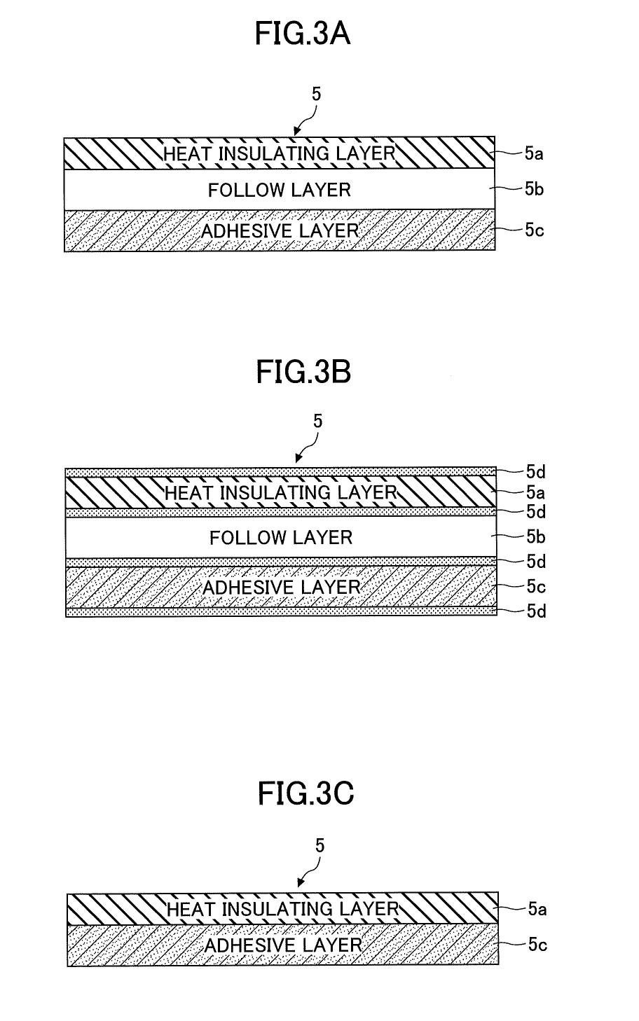

Hereinafter, referring to FIGS. 1 and 2, examples of the mounting stage, in which the heat transfer sheet is provided, and the substrate processing apparatus of the embodiment are explained.

FIG. 1 illustrates an example of a mounting stage 2 according to an embodiment. The mounting stage 2 includes an electrostatic chuck 12 for mounting a wafer W. An electrostatic chuck 12 for electrostatically adsorbing a wafer W is installed on a base of the mounting stage 2. A focus ring 3 in an annular shape is provided in a step formed at a periphery of the electrostatic chuck 12. In this embodiment, the heat transfer sheet 5 is arranged between the focus ring 3 and the electrostatic chuck 12.

The focus ring 3 is fixed to the electrostatic chuck 12 by, for example, a screw. The focus ring 33 includes a member containing silicon. Within this embodiment, the focus ring 3 is made of silicon (Si) or silicon carbide (SiC).

The focus ring 3 functions to alleviate discontinuity of plasma at a peripheral portion of the wafer W so that the entire surface of the wafer W uniformly undergoes plasma treatment. For this, the focus ring 3 is made of a conductive material, and the height of an upper surface is substantially the same height of the treated surface of the wafer W. Thus, ions are caused to impinge a front surface of the wafer W in a direction vertical to the front surface even at the peripheral portion of the wafer W so that no difference in an ion density occurs between the periphery of the wafer W and the center of the wafer W. Because a temperature control of the wafer W is important in the plasma treatment, a refrigerant flow passage 23 is provided inside the mounting stage 2 so that the temperature of the wafer W is adjusted.

### Example of Structure of Substrate Processing Apparatus

Referring to FIG. 2, an example of an arrangement of the heat transfer sheet 5 in the substrate processing apparatus 1 and the structure of the substrate processing apparatus 1 is described next. The substrate processing apparatus 1 is structured to be a parallel-flat-plate plasma etching apparatus of a capacitively-coupled type, in which the chamber 4 has a substantially cylindrical shape, is made of aluminum having an outer surface undergoing anodic oxidation, and is grounded. The mounting stage 2 for mounting the wafer W is arranged inside the chamber 4. The heat transfer sheet 5 illustrated in FIG. 1 is provided between the electrostatic chuck 12 and the focus ring 3.

An exhaust passage 6 for exhausting a gas is formed between an inner wall surface of the chamber 4 and an outer peripheral surface of the mounting stage 2. An exhaust plate 7 made of a porous plate is provided in a middle of the exhaust passage 6. The exhaust plate 7 functions as a partition plate for partitioning the chamber 4 up and down. An upper part from the exhaust plate 7 forms a reaction chamber 8, and a lower part from the exhaust plate 7 forms an exhaust chamber 9. An exhaust tube 10 is connected to the exhaust chamber 9 so as to communicate with the inside of the exhaust chamber 9. The inside of the chamber 4 is evacuated by a vacuum pump connected to the exhaust tube 10.

The electrostatic chuck 12 is formed such that an upper disk-like member completely overlaps a lower disk-like member and the diameter of the upper disk-like member is smaller than the diameter of the lower disk-like member. The electrostatic chuck 12 is made of dielectric substance (ceramics etc.). An adsorption electrode 12a is provided inside the electrostatic chuck 12. When a direct voltage is applied to an adsorption electrode 12a connected to a direct current source 13, the wafer W is adsorbed and held by Coulomb's force.

The electrostatic chuck 12 is fixed to the mounting stage 2 by a screw. The focus ring 3 surrounds the outer periphery of the wafer W. The surface of the focus ring 3 is exposed to a space of the reaction chamber 8. The focus ring 3 causes plasma inside the reaction chamber 8 to converge on a position above the wafer W.

A gas shower head 16 is provided on a ceiling of the chamber 4. A gas is supplied from a gas introduction tube 19 to gas shower head. The gas is supplied from a large number of blow holes 22 provided in an upper electrode plate 21 through a buffer chamber 20 to a reaction chamber 8. High frequency power is supplied from a high frequency power source 17 to the gas shower head 16. High frequency power is supplied from a high frequency power source 18 to the mounting stage 2. This high frequency power causes the gas to be electrolytically dissociated or dissociated and plasma is generated in a space of the reaction chamber 8.

The wafer W has a high temperature by receiving heat from the plasma. Therefore, the mounting stage 2 is made of metallic material having good thermal conductivity such as aluminum. A refrigerant flow passage 23 is formed inside the mounting stage 2 to cool the mounting stage 2 by circulating a refrigerant such as water. A large number of thermal conduction gas supply apertures 24 are formed on a surface of adsorbing the wafer W. Helium having good thermal conductivity is flown out of the thermal conduction gas supply apertures 24 to cool the back surface of the wafer W so as to enhance thermal conductivity between the wafer W and the mounting stage 2. As described, the temperature of the wafer can be adjusted by the refrigerant or the thermal conduction gas.

### Example of Structure of Heat Transfer Sheet

In this embodiment, a heat transfer sheet 5 is arranged between the electrostatic chuck 12 and the focus ring 3 so that heat of the focus ring 3 is transferred to the mounting stage 2 so that the temperature of the upper surface of the focus ring 3 is controlled. However, in a case where an annular aluminum ring is arranged on a step in the periphery of the electrostatic chuck 12, the focus ring 3 may be arranged on the aluminum ring interposing the heat transfer sheet 5 between the focus ring 3 and the aluminum ring. Described next is the heat transfer sheet 5 of the embodiment.

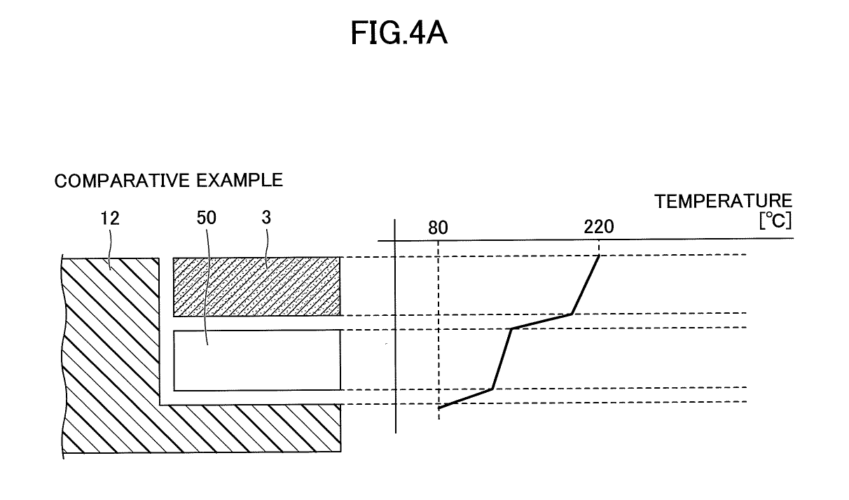

The heat transfer sheet 5 is a polymer sheet having a laminate structure of multiple layers. FIGS. 3A-3C illustrate structures of the heat transfer sheet 5. The heat transfer sheet 5 illustrated in FIG. 3A has a three-layer structure including a heat insulating layer 5a, a follow layer 5b, and an adhesive layer 5c. The heat insulating layer 5a has thermal conductivity lower than thermal conductivity of the focus ring 3. The thermal conductivity of the heat insulating layer 5a is equals to or less than 2.2 (W/m·K). The heat insulating layer 5a includes at least any one of high-polymer material, zirconia, quartz, silicon carbide, and silicon nitride. The heat insulating layer 5a may include a porous body having a predetermined porosity.

The follow layer 5b is provided between the heat insulating layer 5a and the adhesive layer 5c and is made of a material having a higher linear expansion coefficient than that of the heat insulating layer 5a. An example of the material of the follow layer 5b is silicone gum, a silicone resin, and a cross-linking agent. The follow layer 5b may be made of any one of the silicone gum, the silicone resin, and the cross-linking agent and another element included therein, or may be made of a resin.

The adhesive layer 5c has adhesiveness higher than the heat insulating layer 5a. The adhesive layer 5c preferably has a hardness ratio represented by Ascar C is equals to or less than 17. The adhesive layer 5c may be made of any one of the silicone gum, the silicone resin, and the cross-linking agent and another element included therein, or may be made of a resin.

In the heat transfer sheet 5 of the embodiment, the upper surface of the heat insulating layer 5a contacts the focus ring 3, and the lower surface of the adhesive layer 5c contacts the electrostatic chuck 12. Because the heat transfer sheet 5 has the laminate structure of the above three layers respectively having properties, a thermal insulation property, contact, and a thermal follow capability are performed.

Said differently, in the heat transfer sheet 5, the heat insulating layer 5a exists. Heat of the focus ring 3 generated by the heat from the plasma is hardly transmitted onto a side of the mounting stage 2 so that the temperatures of the follow layer 5b and the adhesive layer 5c are kept to be low.

Further, in the heat transfer sheet 5, since the adhesive layer 5c exists, the heat transfer sheet 5 having strong contact can be substantialized so that the heat transfer sheet is prevented from peeling off by a linear expansion difference between the members.

Further, because the heat transfer sheet 5 includes the follow layer 5b, the heat transfer sheet 5 can have higher followability to a linear expansion difference and high elasticity. Therefore, the heat transfer sheet 5 can sufficiently follow the linear expansion difference between the focus ring 3 and the electrostatic chuck 12. Further, the temperature of the sheet in the lower layer of the heat transfer sheet 5 by the heat insulating layer 5a. Therefore, even under a high temperature process at 250° C. or higher, the oil bleeding can be prevented and the focus ring 3 can be stably used for a long time. Furthermore, in the environment where thermal cycles are repeated, the heat transfer sheet 5 is prevented from peeling off and can be stably used for a long time.

As described, the heat transfer sheet 5 of the embodiment does not cause a change in properties under a temperature environment of 250° C. or higher and can be used for a process performed in the substrate processing apparatus 1 under the temperature of 250° C. or higher.

FIG. 3B illustrates an example of another structure of the heat transfer sheet 5. As illustrated in FIG. 3B, the heat transfer sheet 5 may have a thermal diffusion layer 5d in addition to the heat insulating layer 5a, the follow layer 5b, and the adhesive layer 5c. The thermal diffusion layer 5d is provided in the front surface of the heat transfer sheet or the internal interlayer and has a function of dispersing heat in a lateral direction (a direction parallel to a layer). The thermal diffusion layer 5d may be made of a metal-containing tape such as an aluminum tape and a carbon tape.

Referring to FIG. 3B, although the thermal diffusion layer 5d is provided on the heat insulating layer 5a, the follow layer 5b, the interlayer of the adhesive layer 5c, the upper surface of the heat insulating layer 5a, and the lower surface of the adhesive layer 5c, the location of the thermal diffusion layer 5d is not limited thereto. It is sufficient that at least one layer of the thermal diffusion layer 5d is provided on at least one of the interlayers, the upper surface of the heat insulating layer 5a, and the lower surface of the adhesive layer 5c. However, if at least two layers of the thermal diffusion layers 5d are provided, the thermal diffusion effect becomes preferably high.

Referring to FIG. 3C, the heat transfer sheet 5 has a three-layer structure of laminating the heat insulating layer 5a and the adhesive layer 5c sequentially beginning at the top. However, the heat transfer sheet 5 more preferably has the layer structure including, the heat insulating layer 5a, the follow layer 5b, and the adhesive layer 5c.

### Example of Effect of Heat Transfer Sheet

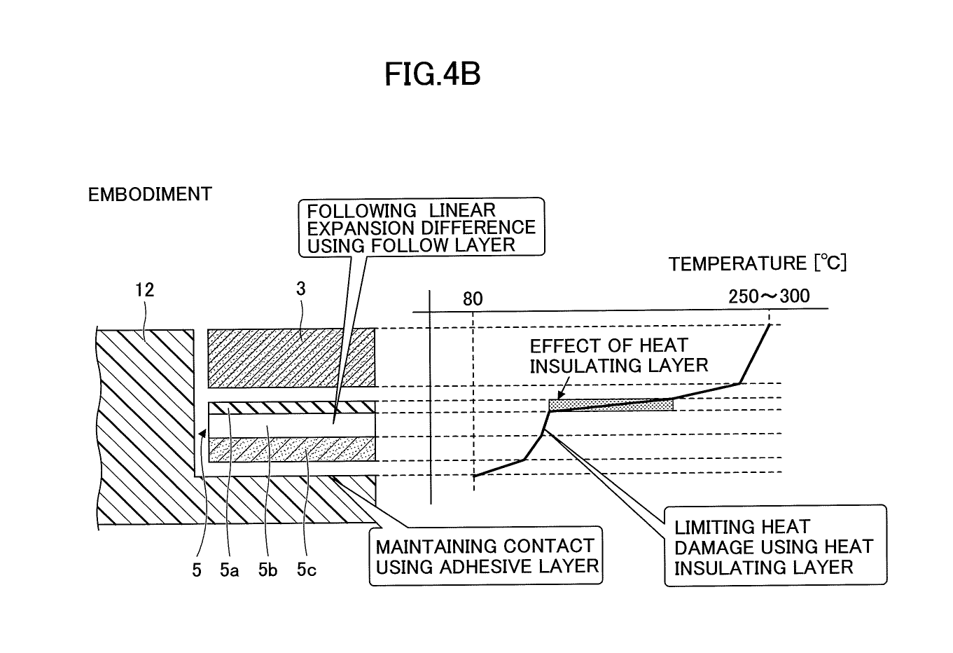

Referring to FIG. 4, the property of the heat transfer sheet 5 of the embodiment is described in comparison with the heat transfer sheet of the comparative example. FIG. 4A illustrates an example of the property of the heat transfer sheet 50 when the heat transfer sheet 50 of the comparative example is used. FIG. 4B illustrates an example of the property of the heat transfer sheet 5 when the heat transfer sheet 50 of the embodiment is used.

The heat transfer sheet 5 of the embodiment used in this test has the three-layer structure including the heat insulating layer 5a, the follow layer 5b, and adhesive layer 5c illustrated in FIG. 3A. The heat transfer sheet 50 of the comparative example is enabled to prevent degradation by adding a reaction inhibiting additive agent and restricting oxidation of the heat transfer sheet 50. Composition of silicone adhesive for the heat transfer sheet 50 of the comparative example include three components of silicone gum as an elastomer, a silicone resin as a tackifier agent, and a cross-linking agent.

In this test, plasma is generated by the substrate processing apparatus 1, in which the heat transfer sheet 5 or the heat transfer sheet 50 is provided between the focus ring 3 and the electrostatic chuck 12. As a result, the focus ring 3 has a high temperature by receiving heat from the plasma. Referring to FIG. 4A, when the heat transfer sheet 50 of the comparative example is used, a heat insulating effect of the heat transfer sheet 50 is insufficient and therefore heat is tend to transmit from the focus ring 3 to the electrostatic chuck 12. As a result, when the temperature of the electrostatic chuck 12 is 80° C., it is limited to use within a range where the temperature of the focus ring 3 increasing up to 220° C. in order to prevent degradation of the heat transfer sheet 50.

Referring to FIG. 4B, when the heat transfer sheet 5 of the embodiment is used, a thermal insulation property of the heat transfer sheet 50 is high and therefore heat is hard to transmit from the focus ring 3 to the electrostatic chuck 12. As a result, when the temperature of the electrostatic chuck 12 is 80° C., even if the temperature of the focus ring 3 becomes 250° C. to 300° C., the temperature of the lower layer of the heat insulating layer 5a can be maintained to be low, and therefore the heat transfer sheet 5 does not degrade so as to be used for a long time.

By the above test, it is known that the heat transfer sheet 5 performs the thermal insulation property especially by the heat insulating layer 5a included in the three-layer structure to reduce a damage caused by heat from the lower layer of the heat insulating layer 5a. Further, the linear expansion difference between the focus ring 3 and the electrostatic chuck 12 can be followed by the follow layer 5b and the adhesive layer 5c so as to maintain a contact between the focus ring 3 and the electrostatic chuck 12.

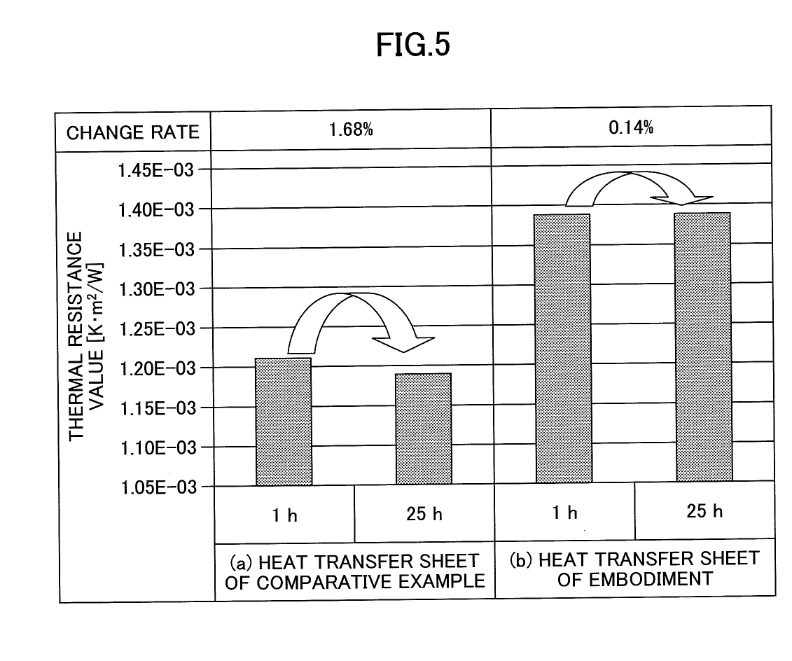

FIG. 5 illustrates an example of a result of comparing the property of the heat transfer sheet 5 of the comparative example with the property of the heat transfer sheet 50 of the embodiment. Both the result in the heat transfer sheet 5 of the comparative example illustrated in (a) of FIG. 5 and the heat transfer sheet 50 of the embodiment are obtained by measuring using a thermal resistance measuring instrument in the substrate processing apparatus 1 after 1 hour or 25 hours elapse while the plasma is generated. Regarding both the heat transfer sheets 5 and 50, thermal resistance values and aging variations after 1 hour and after 25 hours are measured.

With this, the heat transfer sheet 5 illustrated in (b) of FIG. 5 has a greater thermal resistance value indicated in the vertical axis than that in the heat transfer sheet 50. Said differently, the heat transfer sheet 5 has a heat insulating effect about 20% higher than that of the heat transfer sheet 50 of the comparative example.

The change rate of the thermal resistance value between a passage of 1 hour and a passage of 25 hours in the heat transfer sheet 5 of the embodiment is 0.14%, which is lower than the change rate in the heat transfer sheet 50 of the comparative example of 1.68%. Thus, the aging variation in the heat transfer sheet 5 is smaller than that in the heat transfer sheet 50. This is because the heat transfer sheet 5 of the embodiment does not conduct oil bleeding by a heat insulating effect of the heat insulating layer 5a, and therefore there is a little change in a thermal resistance so that the follow layer 5b and the adhesive layer 5c are maintained to have the low temperature. Thus, the heat transfer sheet 5 of the embodiment degrades less than the heat transfer sheet 50 of the comparative example.

As described above, these are known that the heat insulating layer 5a of the heat transfer sheet 5 of the embodiment controls the temperature of the heat transfer sheet 5 to be a high temperature of about 250° C. to 300° C. and the properties of the heat transfer sheet 5 scarcely change. Further, the heat transfer sheet 5 of the embodiment can follow the linear expansion difference between the focus ring 3 and the electrostatic chuck 12 by the follow layer 5b and can maintain the contact with the electrostatic chuck 12 by the adhesive layer 5c. Therefore, it is possible to provide the heat transfer sheet 5, which can be used under a circumstance of at least 250° C.

### [Tension Test]

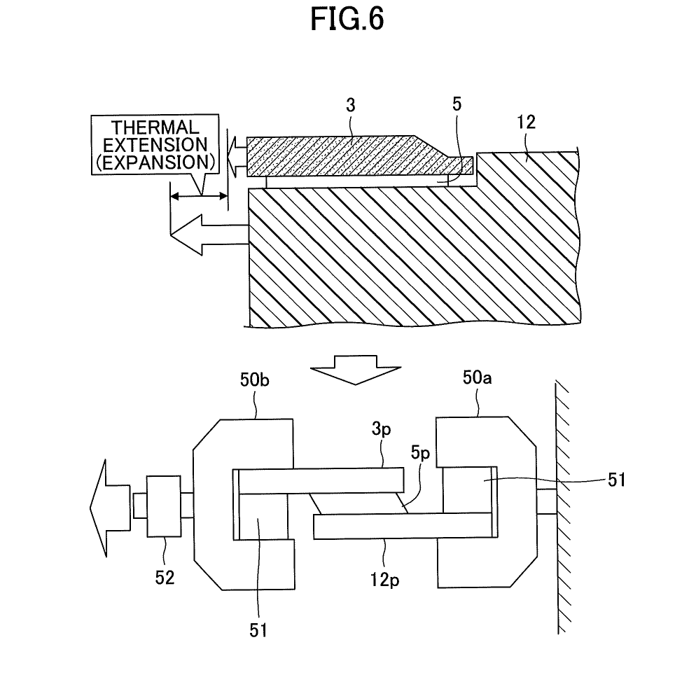

Next, referring to FIGS. 6-9, a tension test (a shearing test) of the heat transfer sheet 5 is described. Within the embodiment, the focus ring 3 is made of silicon (Si) or silicon carbide (SiC), and the electrostatic chuck 12 is made by alumina (Al₂O₃). When each member thermally expands by heat from the plasma, a linear expansion difference (a thermal extension) occurs between the focus ring 3 and the electrostatic chuck 12 like an arrow illustrated in FIG. 6. If the contact of the heat transfer sheet 5 is low, the heat transfer sheet 5 cannot follow the linear expansion difference caused by the temperature change of the focus ring 3 and the electrostatic chuck 12 and therefore is peeled from the focus ring 3 or the electrostatic chuck 12. The contact of the heat transfer sheet 5 is critical to make the heat transfer sheet 5 hard to be peeled from the focus ring 3 or the electrostatic chuck 12. Said differently, by enhancing the contact of the heat transfer sheet 5, it is possible to improve fluctuation of the temperature of the focus ring 3 and enhance temperature controllability of the focus ring 3.

In a tension test described below, a state where the heat transfer sheet 5 is pulled by a linear expansion difference between the focus ring 3 and the electrostatic chuck 12 is simulated by the tension testing machine illustrated by the lower part of FIG. 6.

In the tension testing machine of the embodiment, a test piece 5p of the heat transfer sheet 5 is sandwiched between a test piece 3p of the focus ring 3 and a test piece 12p of the electrostatic chuck 12. In this state, an end of the test piece 3p of the focus ring 3 (an end portion to which the test piece 5p of the heat transfer sheet 5 is not attached) is gripped by a first clamp 50b through a spacer 51. An end of the test piece 12p of the electrostatic chuck (an end portion to which the test piece 5p of the heat transfer sheet 5 is not attached and a position opposite to a position where the focus ring 3 is gripped) is gripped by a second clamp 50b through the spacer 51. While the second clamp 50a is fixed, the load cell 52 pulls the first clamp 50p at a predetermined rate on a side opposite to a position where the second clamp 50a is fixed. With this, as illustrated in the upper portion of FIG. 6, a state where the heat transfer sheet 5 is pulled by a linear expansion difference between the focus ring 3 and the electrostatic chuck 12 is simulated by the test pieces 3p, 5a, and 12a. In this test, the test piece 5p is configured by only the follow layer 5b, and the heat insulating layer 5a and the adhesive layer 5c are not provided. The pulling property can be judged by only the follow layer 5b. Therefore, it is possible to determine the result of the test substantially the same as the pulling property of the heat transfer sheet 5 of the three-layer structure including the heat insulating layer 5a, the follow layer 5b, and the adhesive layer 5c. Further, the result of this test may be determined similar to the pulling property of the heat transfer sheet 5 of the two-layer structure including the heat insulating layer 5a and the adhesive layer 5c which has a property similar to the follow layer 5b. The test piece 5p used for the test has a thickness in a range of ±25% of 0.5 mm and an area of 16.5 mm×16.5 mm.

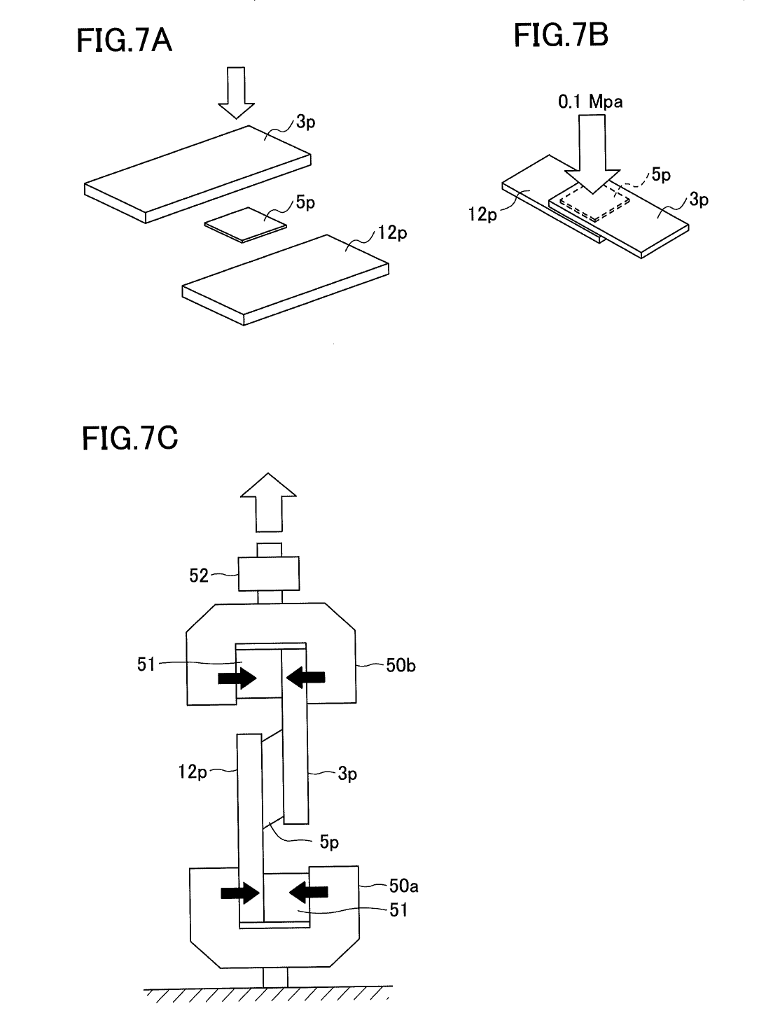

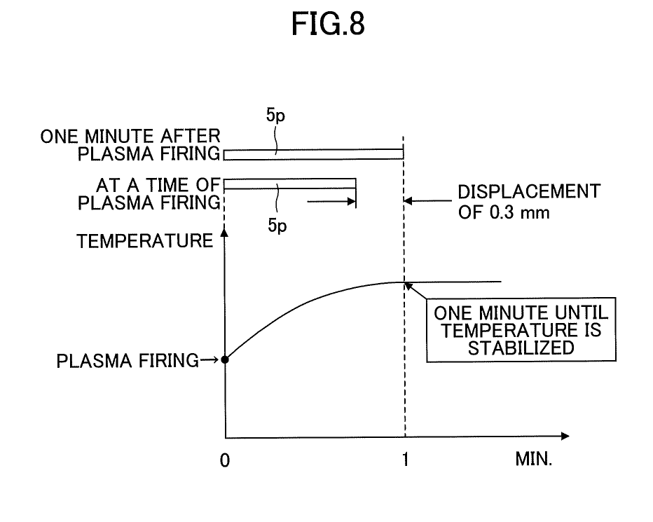

Referring to FIGS. 7 and 8, a measurement method of the pulling property of the test piece 5p of the heat transfer sheet actually conducted using the tension testing machine. FIG. 7 illustrates an example of a procedure of the tension test of this embodiment. FIG. 8 illustrates a relation between a time after plasma firing and displacement of the test piece 5p of the heat transfer sheet of this embodiment.

Referring to FIG. 7A, in the tension test, the test piece 5p of the heat transfer sheet 5 as an object to be tested is interposed between a test piece 3p of a rectangular focus ring and a test piece 12p of an electrostatic chuck.

Next, referring to FIG. 7B, the test piece 5p of the heat transfer sheet 5 interposed between the test piece 3p and the test piece 12p is downwardly pressed by a load of 0.1 MPa for 10 minutes. Further, referring to FIG. 7C, the pressed test piece 5p of the heat transfer sheet 5 is set to a tension testing machine in a state where the test piece 5p is interposed between the test piece 3p and the test piece 12p. At this time, the test piece 12p of the electrostatic chuck 12 is gripped by the second clamp 50a and the test piece 3p of the focus ring 3 is gripped by the first clamp 50b so that the test piece 5p of the heat transfer sheet 5 is not applied with force in the lateral direction. The second clamp 50a is fixed and the first clamp 50b is connected to the load cell 52. The load cell 52 vertically pulls in a direction opposite to the second clamp at a speed of 0.5 mm/min. As such, by conducting a tension test for the test piece 5p of the heat transfer sheet 5 using the tension testing machine, the property of the heat transfer sheet 5 using the test piece 5p is measured.

The test piece 3p of the focus ring 3 is an example of a first plate-like member containing silicon, and the test piece 12p of the electrostatic chuck 12 is an example of a second plate-like member containing aluminum.

In this tension test, the test piece 5p of the heat transfer sheet is pulled at a speed of 0.5 mm/min so as to measure the property. Referring to FIG. 8, the starting point (0 min.) of pulling the tension testing machine at a speed of 0.5 mm/min is when plasma is fired. After a lapse of about one minute after the plasma firing, the temperatures of the members (including the focus ring 3 and the electrostatic chuck 12) are stabilized after about one minute. When the test piece 5p of the heat transfer sheet 5 is pulled by the tension testing machine at the speed of 0.5 mm/min, the test piece 5p displaces by 0.3 mm after about one minute from the plasma firing when the temperature inside the chamber is stabilized.

Thus, temperature inside the chamber is stabilized to be constant after about one minute from the plasma firing. Said differently, the linear expansions of the test piece 3p of the focus ring, the test piece 12p of the electrostatic chuck 12, and the test piece 5p of the heat transfer sheet 5 become largest after about one minute after the plasma firing. The amount of displacement of the test piece 5p of the heat transfer sheet 5 is about 0.3 mm/min. At the time one minute after the plasma firing, the amount of displacement of the test piece 5p of the heat transfer sheet 5 is determined depending on the state of the test piece 12p of the electrostatic chuck having the greatest linear expansion coefficient from among the test piece 3p of the focus ring 3, the test piece 12p of the electrostatic chuck 12, and the test piece 5p of the heat transfer sheet 5.

### [Result of Tension Test]

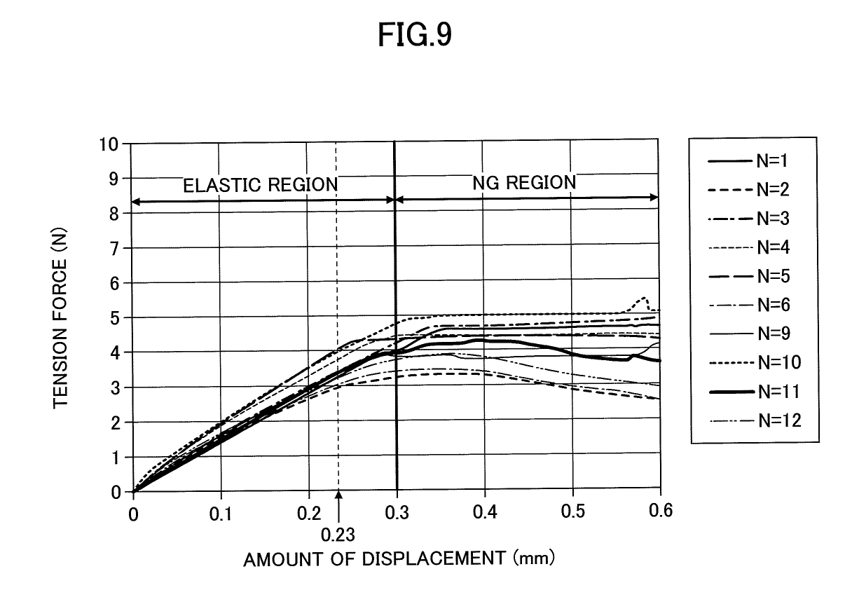

An example of the result of the above tension test is illustrated in FIG. 9. FIG. 9 illustrates the result of a case where the test piece 5p of the heat transfer sheet 5 is pulled by the tension testing machine under the above conditions. Twelve curves (N=1, 2, . . . , 12) indicate pulling force (N) for the amount of displacement (mm) of the test piece 5p of the heat transfer sheet 5 in a case where the test piece 5p is pulled twelve times by the tension testing machine. As a result, ratios of the pulling force relative to the amount of displacement show graphs rising to the right in a range between 0 mm to 0.3 mm. Therefore, it is known that, up to 0.3 mm where the amount of displacement of the test piece 5p of the heat transfer sheet 5 is maximum, the test piece 5p of the heat transfer sheet 5 follows the linear expansions of the test piece 3a of the focus ring 3 and the test piece 12p of the electrostatic chuck 12 to extend without being peeled off. By this measurement, the heat transfer sheet 5 of this embodiment has stronger contact and excellent elasticity so as to be able to sufficiently follow the linear expansion difference.

As such, the test piece 5p scarcely has fluctuation in the property of the test piece 5p. Therefore, reliability of the heat transfer sheet 5 is high. Especially, it is known that the test piece 5p of this embodiment has proper contact force and hardness even though frequency in use becomes higher and is the heat transfer sheet having good thermal conductivity.

Further, from the result of the tension test of the test piece 5p, it is known that the heat transfer sheet 5 of this embodiment has properties of contact force and the hardness, by which the ratio of the pulling force relative to the amount of displacement is 0.1 [N/mm] (substantially horizontal) to 50 [N/mm] (graphs rising to the right) at an amount of displacement 0.3 mm.

In the tension test of this embodiment, the twelve times of tension tests (N=12) are conducted. However, the invention is not limited thereto, and N may be at least two. In the tension test of this embodiment, the side of the second clamp 50a is fixed, and the side of the first clamp 50b is pulled at the predetermined speed. However, the invention is not limited thereto, the side of the second clamp 50b is fixed, and the side of the first clamp 50a may be pulled at the predetermined speed.

The speed of pulling any one of the first clamp 50b and the second clamp 50a is not limited to 0.5 mm/min and may be from 0.1 mm/min to 0.5 mm/min. The amount of displacement of the test piece 5p in a case where the temperature is stabilized after the plasma firing is previously measured in response to the speed at which the clamp is pulled. Therefore, the test piece 5p is sufficient to have contact force and hardness, in which the ratio of the pulling force relative to the amount of displacement of the test piece 5p is 0.1 [N/mm] (substantially horizontal) to 50 [N/mm] (graphs rising to the right) at a time when the temperature is stabilized after the plasma firing. For example, it is sufficient that the ratio Y of the pulling force relative to the amount X of displacement satisfies 0.1 N/mm≤Y≤50 N/mm in a case where the amount X of displacement is in a range of 0 mm≤X≤0.3 mm when the polymer sheet is pulled at a speed between 0.1 mm/min and 0.5 mm/min.

The test piece of the embodiment is sufficient to have the above ratio Y of the pulling force, and fluctuation of the pulling force is in a range of −25% to 25% of the median value of the pulling force when the number N of the tension test is 2≤N≤12 and the amount X of displacement of the heat transfer sheet X is in a range of 0 mm≤X≤0.3 mm.

Further, it is more preferable that the ratio Y of the pulling force relative of the amount X of displacement of the test piece 5p is in a range of 0 N/mm≤X≤50N/mm when the tension test is repeated by the number of times N (2≤N≤12) and the amount X of displacement of the is equal to 0.23 mm (X=0.23 mm), and also the fluctuation of the pulling force is in a range of −15% to 15% of the median value of the pulling force when the number N of the tension test is 2≤N≤12 and the amount X of displacement of the heat transfer sheet X is in a range of 0 mm≤X≤0.3 mm.

As described, the heat transfer sheet 5 of this embodiment has thermal insulation properties by the heat insulating layer 5a. Further, the linear expansion difference between the focus ring 3 and the electrostatic chuck 12 can be followed by the follow layer 5b and the adhesive layer 5c so as to maintain the contact between the focus ring 3 and the electrostatic chuck 12. Therefore, in a case where the temperature of the electrostatic chuck 12 is 80° C., the temperature of the focus ring 3 can be controlled to be at least 250° C. Furthermore, the heat transfer sheet 5 of the embodiment can be used without causing oil bleeding even under the circumstance of at least 250° C.

Although the heat transfer sheet 5 of this embodiment has the two-layer structure of the heat insulating layer 5a and the adhesive layer 5c, the heat insulating layer 5a has the thermal insulation properties to maintain the contact of the electrostatic chuck 12. Further, because the heat transfer sheet 5 of this embodiment has the multilayer structure of the heat insulating layer 5a, the adhesive layer 5c, and at least one thermal diffusion layer 5d, heat in the interlayer in the heat transfer sheet 5 is promoted to be diffused so as to further enhance an accuracy of controlling the temperature of the focus ring 3.

The substrate processing apparatus for the embodiments may be any type of Capacitively Coupled Plasma (CCP), Inductively Coupled Plasma (ICP), Radial Line Slot Antenna, Electron Cyclotron Resonance Plasma (ECR), and Helicon Wave Plasma (HWP).

Within the embodiment, the semiconductor wafer W is described as an example of the substrate. However, the substrate is not limited to this and may be various substrates used for a Liquid Crystal Display (LCD) and a Flat Panel Display (FPD), photomask, a Compact Disk (CD) substrate, a printed wiring board, and so on.

As described, it is possible to provide the heat transfer sheet usable under the circumstance of at least 250° C. or the circumstance of repeating thermal cycles.

All examples and conditional language recited herein are intended for pedagogical purposes to aid the reader in understanding the invention embodiments and the concepts contributed by the inventor to furthering the art, and are to be construed as being without limitation to such specifically recited examples and conditions, nor does the organization of such examples in the specification relate to a showing of superiority or inferiority of the invention embodiments. Although the heat transfer sheet has been described in detail, it should be understood that the various changes, substitutions, and alterations could be made hereto without departing from the spirit and scope of the invention.

What is claimed is:

1. A heat transfer sheet formed of a plurality of layers provided between a mounting stage and a focus ring on an outer side of a substrate to be mounted on the mounting stage inside a plasma treatment apparatus,
wherein the plurality of layers includes
a heat insulating layer having thermal conductivity lower than thermal conductivity of the focus ring, and
an adhesive layer having adhesiveness higher than adhesiveness of the heat insulating layer.

2. The heat transfer sheet according to claim 1,
wherein the plurality of layers are provided between the heat insulating layer and the adhesive layer, and
wherein the plurality of layers includes a follow layer having a linear expansion coefficient higher than a linear expansion coefficient of the heat insulating layer.

3. The heat transfer sheet according to claim 1,
wherein the plurality of layers are provided on a surface of the heat transfer sheet or in an internal interlayer of the heat transfer sheet, and
wherein the plurality of layers includes a follow layer having a linear expansion coefficient higher than a linear expansion coefficient of the heat insulating layer.

4. The heat transfer sheet according to claim 1,
wherein thermal conductivity of the heat insulating layer is 2.2 (W/m·K) or lower.

5. The heat transfer sheet according to claim 1,
wherein the heat insulating layer includes at least a high-polymer material, zirconia, quartz, silicon carbide, and silicon nitride.

6. The heat transfer sheet according to claim 1,
wherein the adhesive layer has a ratio of hardness represented by Ascar C of 17 or smaller.

7. The heat transfer sheet according to claim 1,
wherein the adhesive layer is formed by any one of silicone gum, a silicone resin, and a cross-linking agent.

8. A heat transfer sheet having a predetermined pulling property,
wherein a ratio Y of pulling force relative to an amount X of displacement of the heat transfer sheet is in a range of 0.1 N/mm≤Y≤50 N/mm in a case where the amount X of displacement is in a range of 0 mm≤X≤0.3 mm, the ratio Y being obtained by conducting a test of
pressing the heat transfer sheet interposed between a first plate-like member containing silicon and a second plate-like member containing aluminum;
subsequently gripping one end of the first plate-like member by a first clamp and gripping one end of the second plate-like member by a second clamp at a position opposite to the first clamp; and
subsequently fixing one clamp from among the first clamp and the second clamp and pulling another clamp other than the one clamp at a speed of 0.1 mm/min to 0.5 mm/min on a side opposite to the fixed one clamp by N times where 2≤N, and
wherein fluctuation of the pulling force is in a range of ±25% of a median value of pulling force within the range of the amount X of 0 mm≤X≤0.3 mm.

9. The heat transfer sheet according to claim 8,
wherein the ratio Y of pulling force relative to an amount X of displacement of the heat transfer sheet is in a range of 0.1 N/mm≤Y≤50 N/mm in a case where the amount X of displacement is in a range of 0 mm≤X≤0.23 mm, and
wherein the fluctuation of the pulling force is in a range of ±15% of the median value of pulling force within the range of the amount X of 0 mm≤X≤0.23 mm.

10. A substrate processing apparatus including a focus ring, which is provided on an outer side of a substrate mounted on the mounting stage and contacts the mounting stage through a heat transfer sheet,
wherein the heat transfer sheet is formed of a plurality of layers,
wherein the plurality of layers includes
a heat insulating layer having thermal conductivity lower than thermal conductivity of the focus ring, and
an adhesive layer having adhesiveness higher than adhesiveness of the heat insulating layer.

11. The substrate processing apparatus according to claim 10,
wherein, in the heat transfer sheet, the heat insulating layer contacts the focus ring, and the adhesive layer contacts the mounting stage.
